(19) United States
(12) Patent Application Publication
(10) Pub. No.: US 2024/0074048 A1
(43) Pub. Date: Feb. 29, 2024

(54) SEMICONDUCTOR PACKAGING WITH REDUCED STANDOFF HEIGHT

(71) Applicant: Micron Technology, Inc., Boise, ID (US)

(72) Inventors: Ling Pan, Singapore (SG); Hong Wan Ng, Singapore (SG); Kelvin Tan Aik Boo, Singapore (SG); Seng Kim Ye, Singapore (SG); See Hiong Leow, Singapore (SG)

(21) Appl. No.: 17/894,070

(22) Filed: Aug. 23, 2022

(51) Int. Cl. H05K 1/11; H01L 23/00; H01L 25/065; H05K 1/18; H05K 3/46

(52) U.S. Cl. CPC H05K 1/111; H01L 24/16; H01L 25/0657; H05K 1/181; H05K 3/4644; H01L 2224/16013; H01L 2224/16014; H01L 2224/16237; H01L 2225/0652; H05K 3/3436; H05K 2201/09472; H05K 2201/10159; H05K 2201/10734

(57) ABSTRACT

A semiconductor device assembly includes a semiconductor die, a substrate carrying the semiconductor die, and a printed circuit board (PCB) coupled to the substrate. The PCB includes a primary conductive layer including a first surface of the substrate and a first solder mask layer coupled to the first surface. The substrate also includes a secondary conductive layer including a second surface of the substrate and a second solder mask layer coupled to the second surface. The substrate further includes an inner conductive layer positioned between the primary layer and the secondary layer, where the inner layer includes a bond pad positioned at the end of an opening that extends from the first solder mask layer through the primary layer to the bond pad of the inner layer. By attaching a solder ball to the bond pad of the inner layer, standoff height is reduced.

### TECHNICAL FIELD

The present technology generally relates to semiconductor devices, and more particularly relates to semiconductor device packaging having reduced standoff height.

### BACKGROUND

Packaged semiconductor dies, including memory chips, microprocessor chips, and imager chips, typically include a semiconductor die mounted on a substrate and encased in a protective covering. The semiconductor die can include functional features, such as memory cells, processor circuits, and imager devices. In turn, the substrate can be bonded to a printed circuit board (PCB) of a larger package. Semiconductor device manufacturers continually seek to make smaller, faster, and more powerful devices with a higher density of components for a wide variety of products, such as computers, cell phones, watches, cameras, and more.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1 is a side cross-sectional view of a semiconductor device assembly in accordance with embodiments of the present technology.

FIG. 2 is a side cross-sectional view of a semiconductor device assembly in accordance with embodiments of the present technology.

FIG. 3 is a side cross-sectional view of a semiconductor device assembly in accordance with embodiments of the present technology.

FIG. 4 is a flowchart illustrating a process for producing a semiconductor device assembly in accordance with embodiments of the present technology.

FIG. 5 is a schematic view of a system that includes a semiconductor device or package configured in accordance with embodiments of the present technology.

### DETAILED DESCRIPTION

To meet continual demands on decreasing size, individual semiconductor dies or active components are typically manufactured in bulk and then stacked on a substrates. To facilitate electrical connection between semiconductor dies and external components, such as on a PCB, substrates typically include a conductive layer with designated bond pads and a solder mask material that insulates the conductive layer and includes openings that expose the designated bond pads.

Manufacturers continually seek to decrease the height of semiconductor device packaging. For example, solid state drives (SSDs) are often required to meet specific form factor requirements. At the same time, SSDs are being manufactured with increasing numbers of memory layers, and minimum die thickness is also increasing as circuitry becomes more complex.

One method to reduce the height of semiconductor packaging is to reduce the size of solder joints used to connect components of the package, thus reducing the solder joint's standoff height. For a layered substrate, these solder joints are conventionally formed on an outermost conductive layer, such as part of a ball grid array (BGA). However, reducing the size of the solder joints often introduces solder joint reliability issues. Smaller solder joints are more susceptible to mechanical vibrations, thermal shock, or fatigue failure caused by repetitive or cyclic loading compared to larger solder joints. For instance, as solder joint size is reduced, it becomes more likely to form cracks, causing the connection to fail. As a result, other, more reliable, methods of reducing the height of semiconductor packaging are needed.

Introduced are substrates and associated systems and methods designed to reduce the standoff height of semiconductor packaging. Embodiments of the substrate disclosed herein are multi-layer substrates, where a bond pad located on an inner conductive layer of the substrate. For example, the bond pad can be coupled to the inner layer without an intervening support via. The bond pad is configured to receive a conductive structure, such as a solder ball, through an opening that extends through an outer layer of the substrate to the bond pad on the inner layer. As a result, a solder ball coupled to the bond pad will be recessed into the substrate, decreasing the overall package height. Compared to conventional layered substrates, where bond pads are located at an outermost conductive layer, the substrate with a bond pad on an inner conductive layer has reduced package height even when the same size solder joint is used. As a result, the reliability issues caused by smaller solder joint sizes can be reduced.

The bond pad on the inner conductive layer of the substrate can receive a conductive structure, such as a solder ball. The substrate can be a printed circuit board (PCB) that is coupled via the bond pad to an external connection, e.g., to an interposer substrate carrying a semiconductor device. In some embodiments, the PCB includes a plurality of bond pads located on an inner layer of the PCB and is configured to receive one or more BGA components. In some embodiments, both the PCB and the interposer substrate include a bond pad on respective inner layers, which further reduces the height of the overall package.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

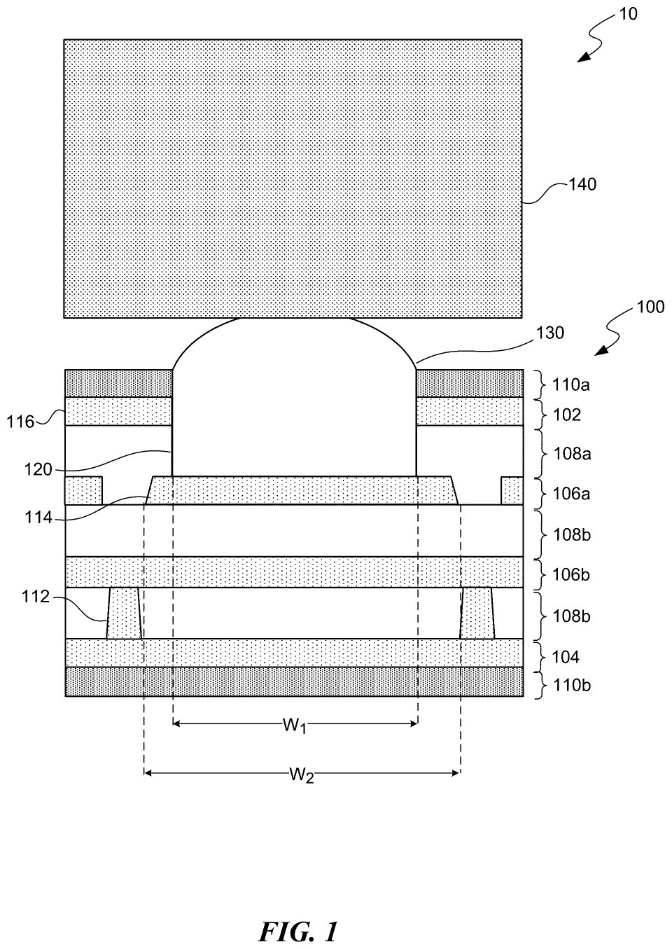

Numerous specific details are disclosed herein to provide a thorough and enabling description of embodiments of the present technology. A person skilled in the art, however, will understand that the technology may have additional embodiments and that the technology may be practiced without several of the details of the embodiments described below with reference to FIGS. 1-5. For example, some details of semiconductor devices and/or packages well known in the art have been omitted so as not to obscure the present technology. In general, it should be understood that various other devices and systems in addition to those specific embodiments disclosed herein may be within the scope of the present technology.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

FIG. 1 is a side cross-sectional view of a semiconductor device assembly 10 in accordance with embodiments of the present technology. The semiconductor device assembly 10 includes a substrate 100 coupled to a semiconductor device 140. The substrate 100 can be a PCB and can carry one or more semiconductor devices 140. The semiconductor device 140 can include a semiconductor die or other active components, which can be encapsulated by a molding (not shown.) In some embodiments, the semiconductor device includes an interposer substrate that carries the semiconductor die. In some embodiments, the semiconductor device 140 can be an SSD component, such as a controller die or memory (e.g., NAND).

The substrate 100 includes a primary layer 102, a secondary layer 104, and inner layers 106a-b. The primary layer 102, secondary layer 104, and inner layers 106a-b are conductive layers (e.g., copper) that include one or more conductive structures, such as bond pads or traces. A primary solder mask 110a is formed on a surface of the primary layer 102 and can prevent the conductive structures in the primary layer 102 from oxidation and shorts. Conductive structures within a conductive layer are laterally separated by an insulator, such as a prepreg material or other dielectric. Conductive layers 102, 104, and 106a-b are vertically separated from each other by insulating layers 108a-c. The insulating layers 108 a-c can comprise prepreg or other dielectric material. The solder mask 110a-b can be epoxy or another suitable polymer.

Collectively, the primary layer 102 and the secondary layer 104 are the outermost conductive layers of the substrate 100. FIG. 1 depicts the primary layer 102 as the uppermost conductive layer and the secondary layer 104 as the lowermost conductive layer, although these labels can be applied in the opposite manner. The conductive layers can be connected by a via 112 that extends through an insulating layer 108a-c.

The substrate 100 includes an opening 120 that extends through a primary solder mask layer 110a that is formed on the primary layer 104. The opening 120 further extends through the primary layer 104 and the insulating layer 108a to a bond pad 114 located at the first inner layer 106a. As a result, the sidewalls of the opening 120 comprise material of the secondary solder mask 110b and insulating material (e.g., prepreg) of the secondary layer 104 and the insulating layer 108c. The bond pad 114 is configured to receive a solder ball 130 or another conductive structure (e.g., a conductive pillar,) used to couple the substrate 100 to the semiconductor device 140. By applying the solder ball 130 to the first inner layer 106a instead of the primary layer 102, the overall package height is reduced. In some embodiments, the standoff height can be reduced by approximately 100 μm after reflow.

In addition, applying the solder ball 130 directly to the first inner layer 106a reduces the need for vias (e.g., vias 130,) between the first inner layer 106a and the primary layer 102. Such vias near the solder ball 130 are often points of failure during testing and use. Thus, mounting the solder ball 130 to the bond pad 114 of the inner layer 106a can enhance reliability of the substrate 100.

Beside the first inner layer 106a, the bond pad 114 can be positioned at any inner layer. For example, in some embodiments, the bond pad 114 is positioned at the second inner layer 106b, and the opening extends through the primary solder mask 110a, the primary layer 104, the first inner layer 106a, and the insulating layers 108a-b.

Although the embodiment shown in FIG. 1 includes two inner layers 106a and 106b, in some embodiments, the substrate 100 includes one, three, four or more inner layers 106. One or more bond pads 114 can be positioned at any of these inner layers 106 in various combinations. In some embodiments, the substrate 100 includes multiple bond pads 114 that receive multiple respective solder balls 130 through multiple openings 120, e.g., as part of a BGA. The multiple bond pads 114 can be positioned at the same inner layer 106 or at different inner layers 106. For example, using FIG. 1 as a reference, a first bond pad 114 can be positioned at the first inner layer 106a, and a second bond pad 114 can be positioned at the second inner layer 106b. For bond pads 114 positioned at inner layers 106 at different depths, respective solder balls 130 can be differently sized to ensure that the substrate 100 is level when connected to an external component.

The opening 120 has a width W₁, and the bond pad 114 has a width W₂. In the example substrate 100 of FIG. 1, the width of the bond pad W₂ is greater than or equal to the width of the opening W₁, analogous to a solder mask defined (SMD) pad. Thus, the area of the bond pad 114 in contact with the solder ball 130 is confined by the width of the opening 120, W₁. In some embodiments, the width W₁ of the opening 120 is approximately constant along its depth, from the secondary solder mask 110b to the first inner layer 106a. For example, the width of the opening W₁ can be approximately 500 μm. In other embodiments, the width W₁ of the opening varies as a function of depth.

The opening 120 is shown as facing below the substrate 200, but in some embodiments, the substrate 200 includes an opening 120 facing above the substrate 200. For example, the bond pad 114 can instead be positioned on the inner layer 106b, and the opening 120 can face upward by being formed through the primary solder mask 110a, the primary layer 102 and the insulating layer 108a, thus enabling the solder ball 130 to connect to a component (e.g., a semiconductor die or other active component) above the substrate 100.

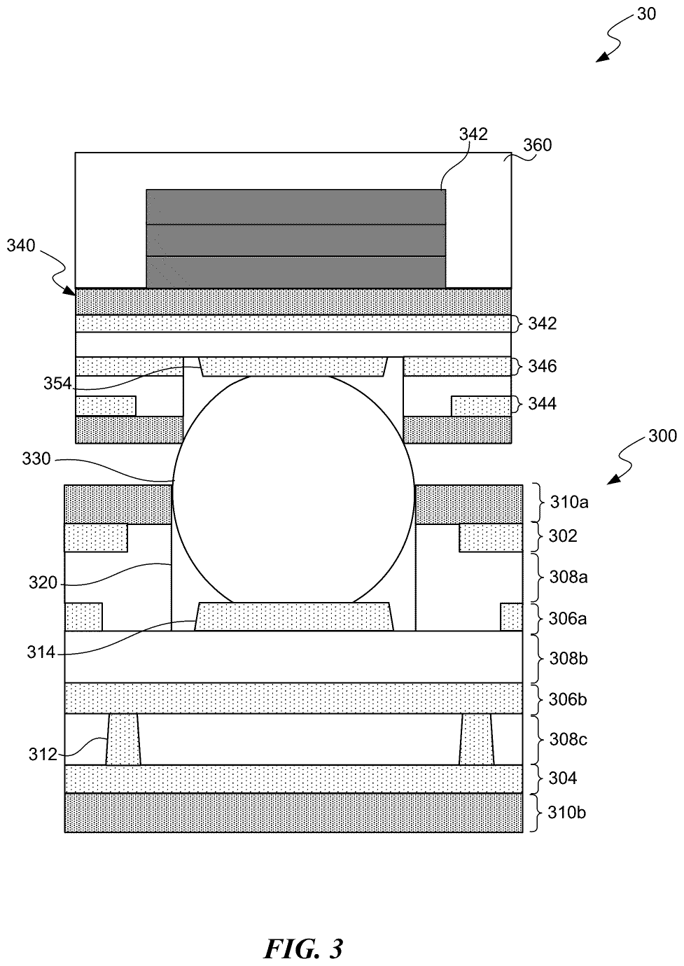

The semiconductor device 140 can include an interposer substrate that is coupled to the substrate 100 by the solder ball 130. A semiconductor die can be coupled to the interposer substrate by conventional methods, e.g., by wire bonding or flip-chip processes. In some embodiments, the interposer substrate has a recessed bond pad similar to the bond pad 114, which can further reduce the overall package height. An example of the interposer substrate is shown below in FIG. 3.

In the example shown in FIG. 1, the insulating layer 108a, primary layer 102, and primary solder mask 110a collectively form a sidewall of the opening 120. The sidewall of the opening 120 thus comprises material of the insulating layer 108a, the primary layer 102, and the primary solder mask 110a. For example, in embodiments where the primary layer 104 is comprised of prepreg, the sidewall of the opening 120 also comprises prepreg.

In some embodiments, the substrate 100 includes a conductive portion 116 that is exposed in the sidewall of the opening 120. The conductive portion 116 exposed in the sidewall enables additional electrical connections to the solder ball 130. In some embodiments, the conductive portion 116 is included in the primary layer 102. For instance, as shown in FIG. 1, the solder ball 130 can electrically couple both the bond pad 114 and the conductive portion 116 of the primary layer 102 to an external component, without additional vias between the primary layer 104 and the inner layer 106a. In some embodiments, the sidewall of the opening 120 is insulated from the solder ball 130. For example, the conductive portion 116 can be separated from the opening by prepreg or another insulating material instead of being exposed.

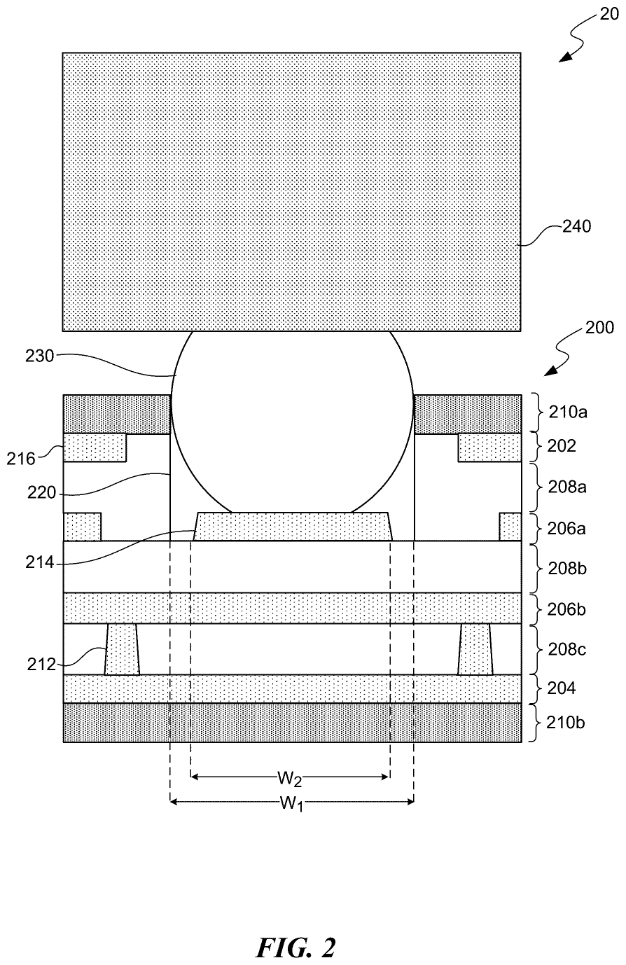

FIG. 2 is a side cross-sectional view of a semiconductor device assembly 20 in accordance with embodiments of the present technology. The semiconductor device assembly 20 includes a substrate 200 coupled to a semiconductor device 240. The substrate 200 is similar to the substrate 100 of FIG. 1. The substrate 200 can be a PCB and can carry one or more semiconductor devices 140. The semiconductor device 140 can include a semiconductor die or other active components, which can be encapsulated by a molding (not shown.) In some embodiments, the semiconductor device includes an interposer substrate that carries the semiconductor die. In some embodiments, the semiconductor device 140 can be an SSD component, such as a controller die or memory (e.g., NAND).

The substrate 200 includes a primary layer 202, a secondary layer 204, and inner layers 206a-b. The primary layer 202, secondary layer 204, and inner layers 206a-b include one or more conductive structures, such as bond pads or traces. A primary solder mask 210a is formed on a surface of the primary layer 202 and a secondary solder mask 210b is formed on the secondary layer 204. The conductive layers 202, 204, and 206a-b are vertically separated from each other by insulating layers 208a-c. The insulating layers 208a-c can comprise prepreg or other dielectric material. The conductive layers 202, 204, and 206a-b can be connected by a via 212 that extends through an insulating layer 208a-c.

Similar the substrate 100 of FIG. 1, the substrate 200 includes an opening 220 that extends through the primary solder mask 210a, the primary layer 202, and the insulating layer 208a to a bond pad 214 located at the first inner layer 206a. The bond pad 214 is configured to receive a solder ball 230 or another conductive structure (e.g., a conductive pillar,) used to couple the substrate 200 to an external component. Similar to the substrate 100 of FIG. 1, the substrate 200 can include one or more bond pads 214 positioned at any of these inner layers 206 in various combinations. In addition, there can be any number of inner layers 206, such as one, two, three, etc.

In contrast to the bond pad 114 of the substrate 100, the bond pad 214 is non-solder mask defined (NSMD.) The width W₁ of the opening 220 is greater than the width W₂ of the bond pad 214. In this case, the entire area of the bond pad 214 in available for contact with the solder ball 230. In addition, gaps exist at the end of the opening 220 as a result of the smaller width W₂ of the bond pad 214 relative to W₁. Such gaps can be advantageous, for example, to accommodate wider traces. However, a bond pad 214 with a width W₂ that is less than W₁ can be more likely to become lifted or disconnected as a result of stress or shock. In some embodiments, the width of the opening 220 is about 500 μm, such as between 450-550 μm, and the solder ball 230 can have a diameter of about 450 μm prior to reflow.

Also in contrast to the substrate 100 shown in FIG. 1, the sidewalls of the opening 220 are separated from any conductive structures, such as conductive portion 216. For instance, the sidewall can be comprised of a prepreg material. As shown, the conductive portion 216 is separated from the opening 220 by an insulating material included in the secondary layer 204.

Although FIGS. 1 and 2 depict differences regarding the widths W₁ and W₂, along with differences in the conductive portions 116 and 216, various embodiments can have different combinations of these features. For example, embodiments of the substrate 200 can include an NSMD bond pad 214 and a conductive portion 216 that is directly coupled to the solder ball 230. In another example, the substrate 200 can include a SMD bond pad and a conductive portion 216 that is separated from the solder ball 230 by an insulating material.

FIG. 3 is a side cross-sectional view of a semiconductor device assembly 30, in accordance with embodiments of the present technology. The semiconductor device assembly 30 includes a first substrate 300 and a second substrate 340. In some embodiments, the first substrate 300 and the second substrate 340 are different types of substrates. For instance, the first substrate 300 can be a system-level substrate, such a PCB, while the second substrate 340 can be an interposer substrate and carry one or more semiconductor dies 342, such as a stack of memory. The second substrate 340 can be coupled to the semiconductor dies 342 by any suitable process, such as wire bonding or flip-chip bonding. The semiconductor dies 342 carried by the second substrate 340 can be encapsulated by an encapsulant 360 such as epoxy molding compound or other resin.

In some embodiments, the first substrate 300 is a PCB configured to carry components of an SSD. The second substrate 340 can then be an interposer used to mount any suitable SSD component, such as flash memory (e.g., NAND), DRAM, or a controller.

The substrate 300 is similar to the substrates 100 and 200 of FIGS. 1 and 2. The substrate 300 includes an inner layer 306a that is conductive and is separated from a primary layer 302 by an insulating material, such as a prepreg or dielectric. The substrate 300 can include solder mask layers 310a-b.

The inner layer 306a includes a bond pad 314, which is at an end of an opening 320. The opening 320 extends from a primary solder mask 310a, through a primary layer 302 to the inner layer 306a. A solder ball 330 coupled to the bond pad 314 at the end of the opening 320 is thus recessed compared to solder balls applied to conventional substrates.

The second substrate 340 includes a bond pad 354 that is positioned at an inner layer 346 of the second substrate 340. The inner layer 346 is separated by a primary layer 342 and a secondary layer 344 by insulating material, such as prepreg or dielectric. Insulating material used in the first substrate 300 can be different than insulating material used in the second substrate 340. The bond pad 354 resides in an opening and is configured to receive the solder ball 330 through that opening. The bond pad 354 is depicted as an NSMD bond pad, but in some embodiments the bond pad 354 is an SMD bond pad.

The solder ball 330 couples the first substrate 300 and the second substrate 340. The bond pad 314 at the inner layer 306a of the first substrate 300, along with the bond pad 354 at the inner layer 346 of the second substrate 340 result in the semiconductor device assembly 30 having reduced standoff height compared to conventional bond pads that are positioned at an outer layer, such as the primary layer 302.

Note that although only one solder ball 330 is shown, the substrates 300 and 340 can coupled by multiple solder balls 330, such as in a BGA. Accordingly, the substrates 300 and 340 can respectively include multiple bond pads 314 and 354 that are aligned with each other. The solder ball 330 can be positioned on a bottom surface of the second substrate 340 and then adjoined with the bond pad 314 on the first substrate 300. The semiconductor device assembly 30 is then heated, such as in a reflow oven, and cooled to form soldered connections between the first substrate 300 and the second substrate 340.

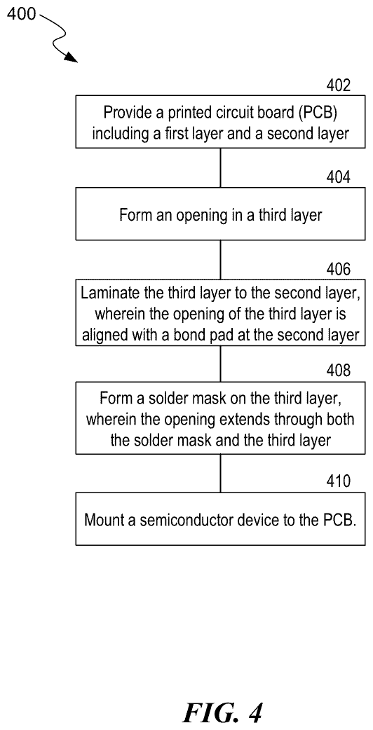

FIG. 4 is a flowchart illustrating a process 400 for producing a semiconductor device assembly, in accordance with embodiments of the present technology. For example, the process 400 can be used to produce the semiconductor device assembly 10, 20, or 30 of FIGS. 1-3.

At 402, a printed circuit board (PCB) including a first layer and a second layer is provided. The first layer and the second layer can be conductive layers, such as a primary, secondary, or inner layer of the PCB. The second layer includes a first side facing toward the first layer and a second side opposite the first side. The second layer further includes a bond pad that is configured to receive a solder ball or other conductive structure. In some embodiments, the first layer or the second layer can include a bond pad configured to receive a solder ball.

At 404, an opening is formed in a third layer. For example, the width of the opening can be approximately 500-600 μm. At 406, the third layer from step 404 is laminated to the second layer. The opening formed at 404 is aligned with the bond pad of the second layer. The opening can be configured to receive a solder ball, such as the solder ball 130, 230, or 330 of FIGS. 1-3. In some embodiments, the width of the opening formed at 404 is greater than the width of the bond pad at the second layer. In some embodiments, the width of the opening is less than or equal the width of the bond pad.

At 408, a solder mask is formed on the third layer. The opening formed at 404 extends through both the solder mask and the third layer. In some embodiments, the opening is formed after laminating the third layer at 406, after forming the solder mask, or after both 406 and 408.

At 410, a semiconductor device is mounted to the printed circuit board. The semiconductor device is mounted by applying a solder ball to the bond pad of the second layer through the opening of the third layer. As a result, the solder ball is recessed at a depth of the opening, which reduces the overall package height relative to forming the solder ball at the third layer. In some embodiments, the semiconductor device includes a memory die or stack of memory, such as NAND or DRAM.

In some embodiments, the semiconductor device is part of an intermediate semiconductor device assembly. For example, the semiconductor device can be mounted on an interposer substrate, and the interposer substrate can be mounted on the PCB. For example, the solder ball can be adjoined to the PCB and then heated. The solder ball can be implemented as one of multiple solder balls in a BGA. In some embodiments, the solder ball is coupled to a semiconductor die, such as a stack of memory dies. The semiconductor die can then be encapsulated by a mold material.

In some embodiments, the interposer substrate includes an inner layer. The inner layer includes a second bond pad. The interposer substrate can further include an outer layer below the inner layer and a second solder mask formed on the outer layer. When the semiconductor device is mounted on the PCB, the second bond pad is coupled to the solder ball applied at 410 through a second opening that extends through the solder mask and the outer layer. Thus, the solder ball applied at 410 is coupled to both the bond pad of the PCB and the second bond pad of the interposer substrate, both of which are recessed. As a result, standoff height is further reduced.

In some embodiments, a solder ball is applied to a bond pad on the third layer. The third layer can be an outer layer, such as a primary or secondary conductive layer. The third layer can also be an inner layer, and additional layers can be laminated to the third layer.

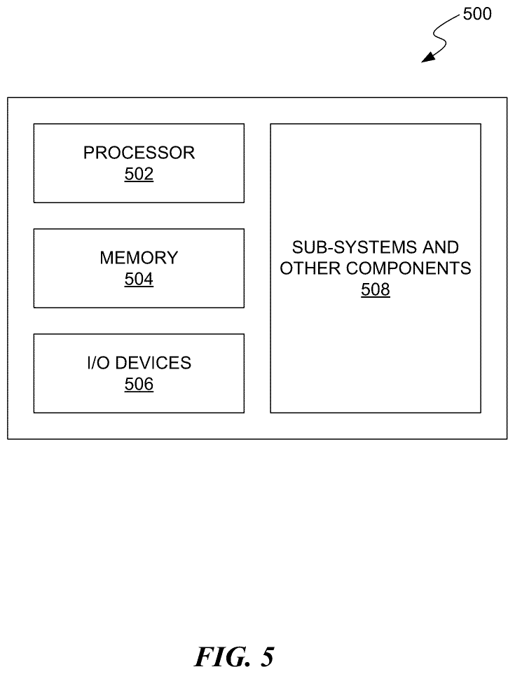

Any one of the semiconductor devices and/or packages having the features described above with reference to FIGS. 1-4 can be incorporated into any of a myriad of larger and/or more complex systems, a representative example of which is system 500 shown schematically in FIG. 5. The system 500 can include a processor 502, a memory 504 (e.g., SRAM, DRAM, flash, and/or other memory devices), input/output devices 506, and/or other subsystems or components 508. The semiconductor dies and/or packages described above with reference to FIGS. 1-4 can be included in any of the elements shown in FIG. 5. The resulting system 500 can be configured to perform any of a wide variety of suitable computing, processing, storage, sensing, imaging, and/or other functions. Accordingly, representative examples of the system 500 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 500 include lights, cameras, vehicles, etc. With regard to these and other example, the system 500 can be housed in a single unit or distributed over multiple interconnected units, e.g., through a communication network. The components of the system 500 can accordingly include local and/or remote memory storage devices and any of a wide variety of suitable computer-readable media.

From the foregoing, it will be appreciated that specific embodiments of the technology have been described herein for purposes of illustration, but that various modifications may be made without deviating from the disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

What is claimed:

1. A semiconductor device assembly comprising:
a semiconductor die;
a substrate carrying the semiconductor die;
a printed circuit board coupled to the substrate, the printed circuit board including:
a primary conductive layer including a first surface;
a first solder mask layer coupled to the first surface;
a secondary conductive layer including a second surface;
a second solder mask layer coupled to the second surface; and
an inner conductive layer positioned between the primary conductive layer and the secondary conductive layer,
wherein the inner conductive layer includes a bond pad positioned at an end of an opening that extends from the first solder mask layer through the primary conductive layer to the bond pad of the inner conductive layer; and
a solder ball attached to the bond pad, wherein the substrate is coupled to the printed circuit board by the solder ball.

2. The semiconductor device assembly of claim 1, wherein the printed circuit board further includes:
a first insulating layer between the primary conductive layer and the inner conductive layer; and
a second insulating layer between the secondary conductive layer and the inner conductive layer.

3. The semiconductor device assembly of claim 1, wherein the substrate is an interposer of the semiconductor device assembly and the printed circuit board is included in a solid-state drive (SSD).

4. The semiconductor device assembly of claim 1, wherein the bond pad is non-solder mask defined (NSMD).

5. The semiconductor device assembly of claim 1, wherein the semiconductor die is a memory die of a stack of memory dies.

6. The semiconductor device assembly of claim 1, wherein the substrate includes:
an inner layer including a bond pad;
an outer layer below the inner layer; and
a solder mask formed on the outer layer,
wherein the bond pad of the substrate is coupled to the solder ball through an opening that extends through the solder mask and the outer layer.

7. The semiconductor device assembly of claim 1, wherein sidewalls of the opening comprise a prepreg material.

8. The semiconductor device assembly of claim 7, wherein the secondary conductive layer includes a conductive portion that is coupled to the solder ball through the sidewalls of the opening.

9. The semiconductor device assembly of claim 1, wherein the opening is one of an array of a plurality of openings, and wherein the solder ball is one of a plurality of solder balls that comprises a ball grid array (BGA).

10. A printed circuit board comprising:
a primary layer including a first surface;
a first solder mask layer coupled to the first surface;
a secondary layer including a second surface;
a second solder mask layer coupled to the second surface; and
an inner layer positioned between the primary layer and the secondary layer,
wherein the inner layer includes a bond pad that is exposed through an opening that extends from the first solder mask layer through the primary layer to the bond pad of the inner layer.

11. The printed circuit board of claim 10, wherein the primary layer, the secondary layer, and the inner layer each include respective conductive structures, and wherein the conductive structures are vertically separated from each other by an insulator.

12. The printed circuit board of claim 10, wherein the bond pad is a first bond pad, the printed circuit board further comprising:
a second bond pad positioned on the primary layer.

13. The printed circuit board of claim 10, wherein the inner layer is a first inner layer, the printed circuit board further comprising:
a second inner layer positioned between the primary layer and the first inner layer,
wherein the second inner layer includes a second bond pad that is configured to receive a second external connection through a second opening that extends from the second solder mask layer through the secondary layer and the first inner layer to the second bond pad.

14. The printed circuit board of claim 10, wherein a width of the bond pad greater than a width of the opening.

15. The printed circuit board of claim 10, wherein the secondary layer includes a conductive portion that is exposed in a sidewall of the opening.

16. The printed circuit board of claim 10, wherein the opening has a diameter of between approximately 500 to 600 μm.

17. A method of producing a semiconductor device assembly comprising:
providing a printed circuit board including a first layer and a second layer, the second layer including:
a first side facing toward the first layer,
a second side opposite the first side, and
a bond pad;
forming an opening in a third layer;
laminating the third layer to the second side of the second layer, wherein the opening of the third layer is aligned with the bond pad of the second layer after laminating;
forming a solder mask on the third layer, wherein the opening of the third layer extends through both the solder mask and the third layer to the bond pad of the second layer;
mounting a semiconductor device to the printed circuit board by:
applying a solder ball to the bond pad of the second layer through the opening of the third layer.

18. The method of claim 17, wherein the semiconductor device is part of an intermediate semiconductor device assembly that includes an interposer substrate, and wherein the interposer substrate is mounted to the printed circuit board.

19. The method of claim 18, wherein the interposer substrate includes:
an inner layer including a second bond pad;
an outer layer below the inner layer; and
a second solder mask formed on the outer layer,
wherein the second bond pad is coupled to the solder ball through a second opening that extends through the solder mask and the outer layer.

20. The method of claim 17, wherein the semiconductor device includes a stack of memory dies.
